(19) United States
(12) Patent Application Publication
(10) Pub. No.: US 2023/0082850 A1
(43) Pub. Date: Mar. 16, 2023

(54) ROBOT HAND

(71) Applicant: DISCO CORPORATION, Tokyo (JP)

(72) Inventor: Atsushi NAKATSUKA, Tokyo (JP)

(21) Appl. No.: 17/823,754

(22) Filed: Aug. 31, 2022

(30) Foreign Application Priority Data
Sep. 13, 2021 (JP) 2021-148338

(51) Int. Cl. B25J 15/06

(52) U.S. Cl. CPC B25J 15/0616; B25J 15/0683; B25J 11/0095

(57) ABSTRACT

A robot hand includes a contactless holding part that has a first air jet port that radially jets air from the center toward the outer circumference, the contactless holding part contactlessly holding a wafer through radial flowing of the air jetted from the first air jet port and generation of a negative pressure due to the air. The robot hand includes also an outer circumferential support part that has a second air jet port that is disposed to be oriented toward the center of the wafer held by the contactless holding part and jets air toward the outer circumferential edge of the wafer, the outer circumferential support part supporting the wafer without movement of the wafer by the air jetted from the second air jet port.

### BACKGROUND OF THE INVENTION

### Field of the Invention

The present invention relates to a robot hand that contactlessly holds a wafer.

### Description of the Related Art

In a processing apparatus that holds a wafer at a chuck table and executes processing of grinding, polishing, or the like for the wafer, the wafer after the processing is conveyed from the chuck table to a spinner table, cleaning is executed, and the cleaned wafer is housed in a cassette by a robot. A robot hand is mounted on the robot, and a holding surface of the robot hand communicates with a suction source. The wafer whose lower surface is suction-held by the spinner table is carried out through suction-holding of the upper surface thereof by the holding surface of the robot hand and is housed in the cassette. There is a fear that the robot hand of a type that gets contact with the upper surface of the wafer and suction-holds the upper surface scratches the upper surface of the wafer. Therefore, a robot hand of a contactless type has also been proposed (for example, refer to Japanese Patent No. 5918771).

### SUMMARY OF THE INVENTION

The robot hand described in the above-described Japanese Patent No. 5918771 is one that gets contact with the outer circumferential edge of the wafer and is not completely contactless. Thus, there is a fear that a wafer is scratched, and there is also a fear that dust occurs due to contact and the wafer after cleaning is contaminated.

Thus, an object of the present invention is to provide a processing apparatus that conveys a wafer by using a robot hand and can house the wafer after cleaning in a cassette completely contactlessly.

In accordance with an aspect of the present invention, there is provided a robot hand that is attached to a robot and contactlessly holds a wafer. The robot hand includes a contactless holding part that has a first air jet port that radially jets air from the center toward an outer circumference and contactlessly holds the wafer through radial flowing of the air jetted from the first air jet port and generation of a negative pressure due to the air. The robot hand includes also an outer circumferential support part that has a second air jet port that is disposed to be oriented toward the center of the wafer held by the contactless holding part and jets air toward an outer circumferential edge of the wafer, the outer circumferential support part supporting the wafer without movement of the wafer by the air jetted from the second air jet port.

Preferably, the contactless holding part includes multiple grooves that extend in the radial direction in such a manner that one ends are located on the central side and the other ends do not reach the outer circumference, the multiple grooves being radially disposed around the center of a holding surface that contactlessly holds the wafer. The grooves become shallower toward the other ends. The first air jet port is disposed at the one ends of the grooves and jets the air to the grooves. The outer circumferential support part has at least a first outer circumferential support part and a second outer circumferential support part disposed to be opposed to each other, and the first outer circumferential support part and the second outer circumferential support part each have at least two of the second air jet ports.

According to the aspect of the present invention, the wafer is contactlessly held by the negative pressure generated due to the air jetted from the first air jet port of the contactless holding part. In addition, the wafer is supported without movement by the air jetted from the second air jet port of the outer circumferential support part. Therefore, the wafer can be held completely contactlessly, scratching of the wafer can be prevented, and the occurrence of dust due to contact and contamination of the wafer after cleaning can be prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating one example of a grinding apparatus;

FIG. 2 is a perspective view illustrating one example of a robot hand;

FIG. 3 is a perspective view illustrating an example of a contactless holding part of the robot hand;

FIG. 4 is a sectional view along line A-A in FIG. 2;

FIG. 5 is a perspective view illustrating an example of an outer circumferential support part of the robot hand;

FIG. 6 is a plan view illustrating one example of the robot hand;

FIG. 7 is a bottom view illustrating the state in which the robot hand that holds a wafer has entered the inside of a cassette;

FIG. 8 is a sectional view illustrating the state in which the robot hand contactlessly holds the wafer;

FIG. 9 is a bottom view illustrating suction force generation regions formed in the contactless holding part of the robot hand;

FIG. 10 is an enlarged sectional view illustrating the state in which the wafer is supported by the outer circumferential support parts;

FIG. 11 is a bottom view illustrating a second example of the robot hand;

FIG. 12 is a bottom view illustrating a third example of the robot hand; and

FIG. 13 is a perspective view illustrating an outer circumferential support part of the robot hand of the third example.

### DETAILED DESCRIPTION OF THE PREFERRED EMBODIMENT

An embodiment of the present invention will be described below with reference to the accompanying drawings.

1 Configuration of Grinding Apparatus

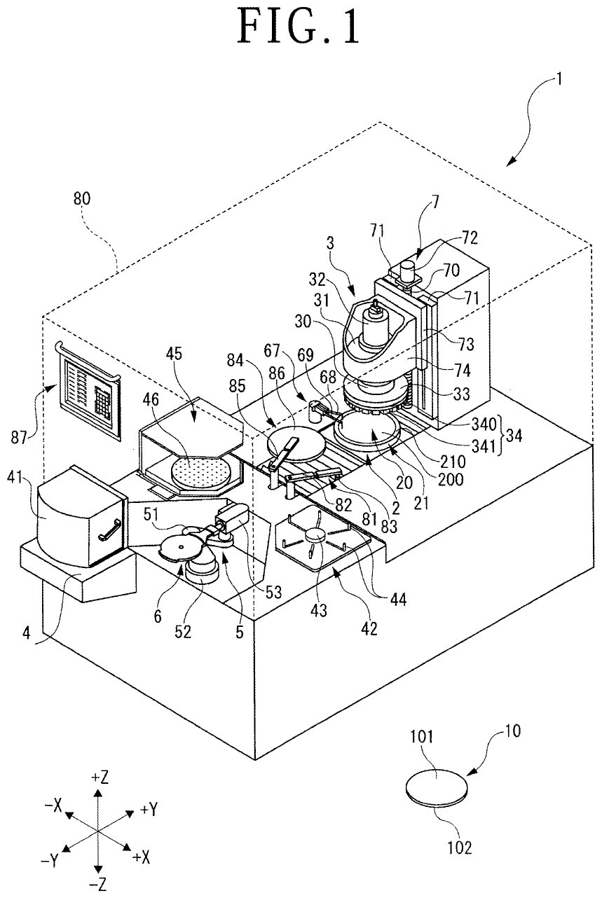

A grinding apparatus 1 illustrated in FIG. 1 is a processing apparatus that grinds a wafer 10 held by a chuck table 2 by a grinding unit 3. The grinding apparatus 1 includes a cassette placement region 4 on which a cassette 41 that houses a wafer 10 of a grinding target is placed at a front part (on the side of a −Y direction) of the grinding apparatus 1.

A robot 5 that carries out the wafer 10 from the cassette 41 and carries in the wafer 10 to the cassette 41 is disposed near the cassette placement region 4. The robot 5 includes an arm 51 that can bend and pivot, a raising-lowering drive part 52 that raises and lowers the arm 51, and a rotational drive part 53 including a motor to which a robot hand 6 is attached and that rotates the robot hand 6 around a rotation axis in a horizontal direction.

A temporary placement region 42 that adjusts the position of the wafer 10 to a constant position is disposed in the motion range of the robot hand 6. In the temporary placement region 42, a placement table 43 on which the wafer 10 is placed, and multiple pins 44 that can move in the radial direction of the placement table 43 are included. The position of the wafer 10 placed on the placement table 43 can be adjusted to the constant position.

Furthermore, a spinner cleaning unit 45 that cleans the wafer 10 after processing is disposed in the motion range of the robot hand 6. The spinner cleaning unit 45 include a spinner table 46 that holds the wafer 10 and rotates and a nozzle that jets a cleaning liquid toward the wafer 10 held by the spinner table 46 and is not illustrated in the diagram.

A first conveying unit 81 that conveys the wafer 10 from the temporary placement region 42 to the chuck table 2 is disposed near the temporary placement region 42. The first conveying unit 81 includes an arm part 82 that can pivot, rise, and lower and a suction adhesion part 83 attached to the tip of the arm part 82.

A second conveying unit 84 that conveys the wafer 10 from the chuck table 2 to the spinner table 46 is disposed on the −X direction side of the first conveying unit 81. The second conveying unit 84 includes an arm part 85 that can pivot, rise, and lower and a suction adhesion part 86 attached to the tip of the arm part 85.

The chuck table 2 is composed of a suction part 20 formed of a porous component and a frame body 21 that surrounds the suction part 20. A suction source that is not illustrated in the diagram communicates with the suction part 20 and can cause a suction force to act on a holding surface 200 of the upper surface of the suction part. The holding surface 200 and an upper surface 210 of the frame body 21 are formed to be flush with each other.

The chuck table 2 can rotate around a rotation axis in a Z-axis direction and can horizontally move in a Y-axis direction. A thickness measuring instrument 67 that measures the thickness of the wafer 10 held by the chuck table 2 is disposed on a lateral side of the movement path of the chuck table 2 in the Y-axis direction. The thickness measuring instrument 67 includes a first measuring part 68 that measures the height of the holding surface 200 through height measurement of the upper surface 210 of the frame body 21 and a second measuring part 69 that measures the height of the wafer 10 held by the holding surface 200, and calculates the thickness of the wafer 10 by the difference between the measurement value of the first measuring part 68 and the measurement value of the second measuring part 69.

The grinding unit 3 is composed of a spindle 30 having the axial center in the Z-axis direction, a housing 31 that rotatably supports the spindle 30, a motor 32 that rotates the spindle 30, a mount 33 coupled to the lower end of the spindle 30, and a grinding wheel 34 mounted on the mount 33. The grinding wheel 34 is composed of a base 340 attached to the mount 33 and multiple grinding abrasive stones 341 fixed to the lower surface of the base 340 in a circular annular manner. Due to rotation of the spindle 30 by the motor 32, the grinding wheel 34 also rotates.

The grinding unit 3 is supported by a grinding feed unit 7 in such a manner as to be capable of rising and lowering. The grinding feed unit 7 is composed of a ball screw 70 having the axial center in the Z-axis direction, a pair of guide rails 71 disposed in parallel to the ball screw 70, a motor 72 that rotates the ball screw 70, a rising-lowering plate 73 that internally has a nut screwing to the ball screw 70 and has side parts in sliding contact with the guide rails 71, and a holder 74 that is coupled to the rising-lowering plate 73 and holds the grinding unit 3. When the motor 72 rotates the ball screw 70, the rising-lowering plate 73 is guided by the guide rails 71 and rises and lowers, and the grinding unit 3 also rises and lowers in association with this.

The grinding apparatus 1 is covered by a cover 80, and a touch panel 87 used for inputting of a processing condition, displaying, and so forth is disposed on the front face side (−Y direction side).

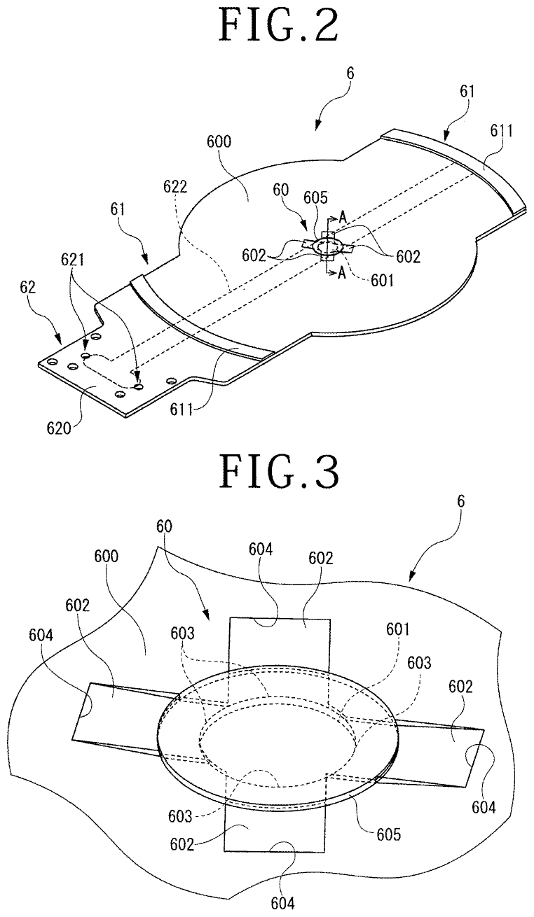

As illustrated in FIG. 2, the robot hand 6 attached to the robot 5 is formed into a flat plate shape and includes a circular contactless holding part 60 that contactlessly holds a surface of the wafer 10, outer circumferential support parts 61 that contactlessly support the outer circumferential edge of the wafer 10, and an attached part 62 attached to the rotational drive part 53 illustrated in FIG. 1.

Air inlets 621 are opened and formed in an upper surface 620 of the attached part 62. The air inlets 621 communicate with an air flow path 622 formed inside.

At the center of an upper surface 600 of the contactless holding part 60, a first air jet port 601 that communicates with the air flow path 622 and is opened to the side of the upper surface 600 is provided. As illustrated in FIG. 3, grooves 602 that radially extend from the first air jet port 601 are formed on the outer circumferential side of the first air jet port 601. The grooves 602 have, as one end 603, the end that is on the central side of the contactless holding part 60 and at a coupling part to the first air jet port 601. The grooves 602 have the other end 604 at a position that exists outside relative to the first air jet port 601 and does not reach the outer circumference of the contactless holding part 60. The grooves 602 extend in the radial direction of the contactless holding part 60. The grooves 602 are formed in such a manner that the depth of the groove 602 is deepest at the one end 603 and becomes shallower toward the other end 604, and the same height as the upper surface 600 is reached at the other ends 604. The other ends 604 of the grooves 602 are located on the inner circumferential side relative to the outer circumference of the wafer 10 to be held.

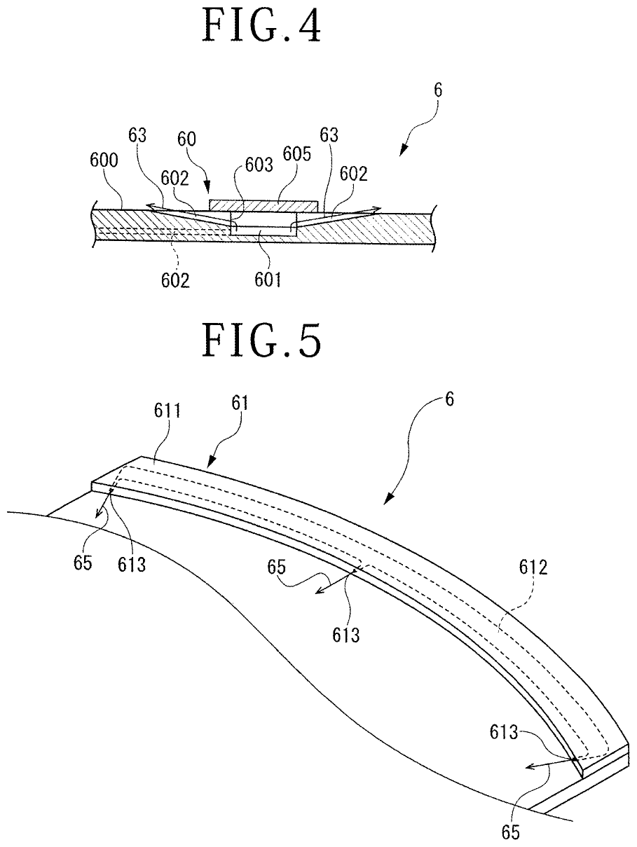

The upper side of the first air jet port 601 is covered by a circular plate 605. The circular plate 605 is bonded to a part in which the groove 602 is not formed in the upper surface 600. As illustrated in FIG. 4, a space exists between the one ends 603 of the grooves 602 and the circular plate 605, and air 63 ejected from the first air jet port 601 is introduced to this space. The air 63 flows along the grooves 602 and along the upper surface 600.

It is preferable that the grooves 602 be disposed symmetrically around the center of the upper surface 600. Furthermore, the grooves 602 may be formed into a fan shape through widening of the side of the other end 604.

As illustrated in FIG. 5, the outer circumferential support parts 61 include the upper surface 600 and a thick wall part 611 that protrudes upward in a circular arc manner from the upper surface 600. In the example illustrated in FIG. 2, two outer circumferential support parts 61 are formed opposed to each other.

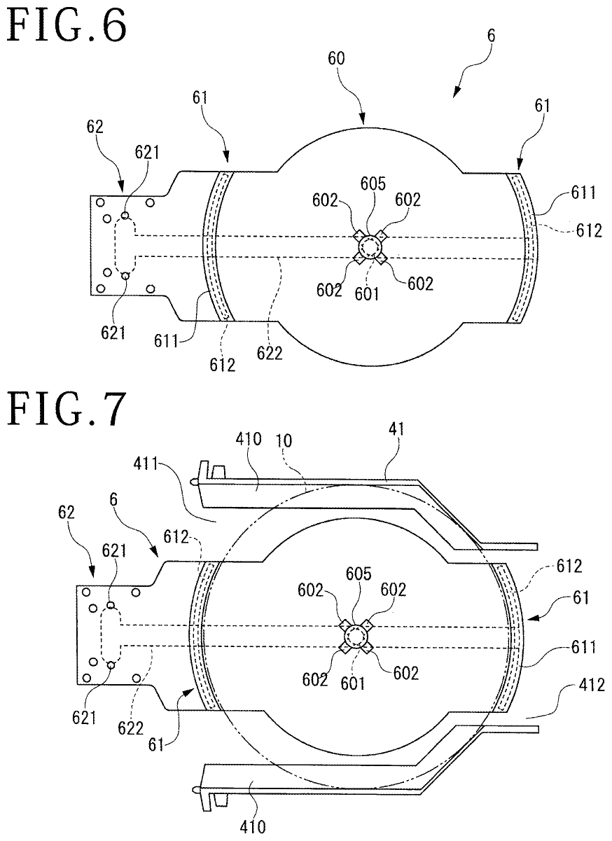

An air flow path 612 is formed inside the thick wall part 611 along the circular arc thereof. In the inner circumferential surface of the thick wall part 611, second air jet ports 613 that are openings that communicate with the air flow path 612 and are opposed to the center of the wafer 10 held by the contactless holding part 60 and eject air 65 toward the center of the wafer 10 are formed. In the illustrated example, three second air jet ports 613 are formed. It suffices that at least one second air jet port 613 is provided in one outer circumferential support part 61 and three or more second air jet ports 613 are provided in total. However, it is desirable that two or more second air jet ports 613 be provided for one outer circumferential support part 61. As illustrated in FIG. 6, the air flow path 622 passes through the lower side of the first air jet port 601 from one outer circumferential support part (first outer circumferential support part) 61 and reaches the other outer circumferential support part 61 (second outer circumferential support part). Furthermore, the diameter of the contactless holding part 60 is set larger than the width of the outer circumferential support parts 61.

That is, the sizes of the first air jet port 601 and the second air jet ports 613 are set in such a manner that air supplied from an air source to the air inlets 621 is ejected from the first air jet port 601 and the second air jet ports 613 as predetermined amounts of air 63 and air 65.

2 Operation of Grinding Apparatus

The wafer 10 before grinding is housed in the cassette 41 of the grinding apparatus illustrated in FIG. 1. For grinding processing of the wafer 10, first, the raising-lowering drive part 52 of the robot 5 adjusts the height of the robot hand 6 to the height of the wafer 10 to be taken out, causes the arm 51 to bend and pivot, and, as illustrated in FIG. 7, causes the robot hand 6 to enter the inside of the cassette 41 from the side of an opening 411. At this time, the rotational drive part 53 illustrated in FIG. 1 inverts the robot hand 6, and thereby the side of the upper surface 600 of the robot hand 6 is oriented downward. The wafer 10 is in a state in which opposed end parts are placed on a pair of shelf plates 410 inside the cassette 41 and are supported, and the robot hand 6 enters the upper side of the wafer 10 to be taken out in such a manner that the wafer 10 is located on the inner circumferential side of the outer circumferential support parts 61. The cassette 41 is one of a type that is referred to as a standard cassette and has an opening on a rear side 412, and the second outer circumferential support part 61 of the robot hand 6 does not interfere with the rear side of the cassette 41.

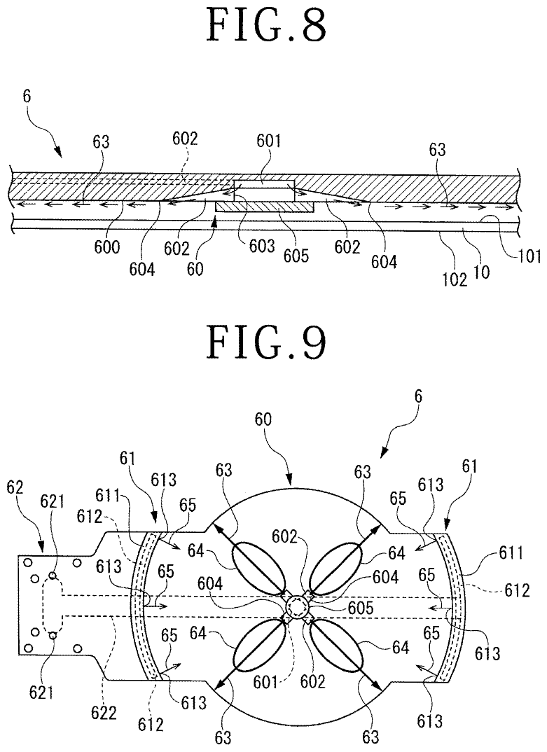

Next, the robot hand 6 is slightly lowered, the upper surface 600 oriented downward due to the inversion is brought closer to an upper surface 101 of the wafer 10, and air is supplied to the air inlets 621. Thereby, as illustrated in FIG. 8, the radial air 63 that goes from the first air jet port 601 toward the grooves 602 and further goes from the grooves 602 toward the outer circumferential side of the contactless holding part 60 is generated. Due to this, a negative pressure is generated on the basis of the Bernoulli effect, and an upward suction force that goes from the upper surface 101 toward the upper surface 600 is generated between the upper surface 600 and the upper surface 101 of the wafer 10. Thus, the wafer 10 is held in a state of being contactless with the upper surface 600 and the upper surface of the circular plate 605 in the contactless holding part 60.

As illustrated in FIG. 9, the air 63 radially flows on extension lines of the grooves 602. Furthermore, suction force generation regions 64 based on the Bernoulli effect are formed on both sides of the air 63.

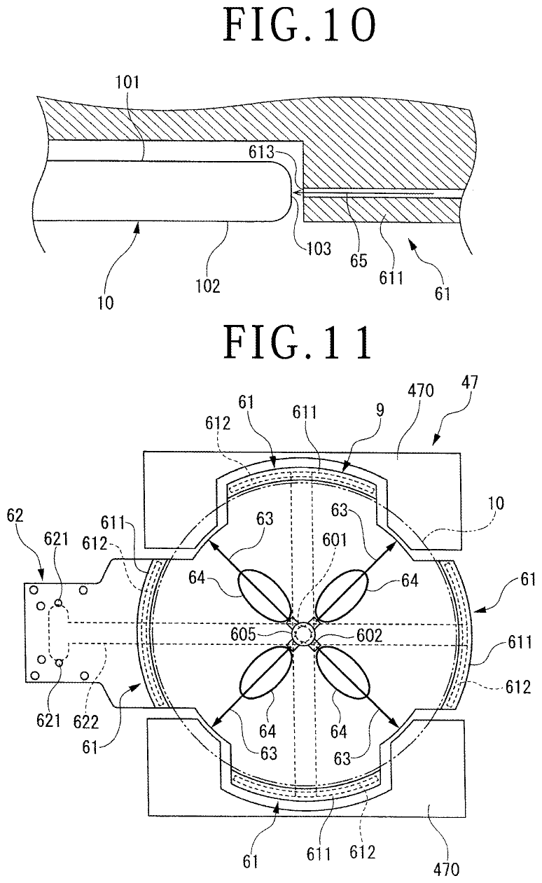

Furthermore, as illustrated in FIG. 10, the air 65 is jetted also from the second air jet ports 613 of the opposed outer circumferential support parts 61. Due to this, an outer circumferential part 103 of the wafer 10 is contactlessly supported in the outer circumferential support parts 61. As illustrated in FIG. 9, the two outer circumferential support parts 61 are disposed to be opposed to each other. Due to this, the outer circumferential part 103 of the wafer 10 is supported from both sides, and therefore the wafer 10 is supported without positional shift in the horizontal direction.

As illustrated in FIG. 9, the other ends 604 of the grooves 602 are oriented in directions in which the thick wall part 611 of the outer circumferential support part 61 does not exist. That is, the other ends 604 are disposed in regions that exist in directions in which the thick wall part 611 does not exist as viewed from the first air jet port 601. Therefore, the air 63 does not go toward the thick wall part 611 and does not interfere with the air 65 jetted from the second air jet ports 613 of the outer circumferential support parts 61. Therefore, both holding of the wafer 10 in the surface direction by the contactless holding part 60 and holding of the wafer 10 in the horizontal direction by the outer circumferential support parts 61 can be achieved without imposing an adverse effect on each other. This can hold the wafer 10 completely contactlessly. The wafer 10 thus held by the robot hand 6 is conveyed to the placement table 43 in the temporary placement region 42 and is placed thereon.

It is also possible to use a robot hand 9 illustrated in FIG. 11 instead of the robot hand 6. The robot hand 9 is different from the robot hand 6 in that the robot hand 9 includes four outer circumferential support parts 61 and in that the air flow path 622 branches in the contactless holding part 60 accordingly.

In a case of using the robot hand 9, it is desirable to use a cassette 47 illustrated in FIG. 11. In the robot hand 9, only parts at which the outer circumferential support parts 61 are formed protrude toward the outer circumferential side and parts toward which the air 63 goes are formed to have a smaller diameter than the outer circumferential support parts 61. The cassette 47 includes a pair of shelf plates 470 corresponding to the shape of the robot hand 9. That is, the shelf plates 470 are formed into a shape that does not interfere with the contactless holding part 60 and the outer circumferential support parts 61 and support the wafer 10 from the lower side only at positions toward which the air 63 goes.

Similarly to the robot hand 6, the robot hand 9 enters the inside of the cassette 47 in the inverted state and holds the upper surface 101 of the wafer 10 by a negative pressure generated due to air that is jetted from the first air jet port 601 of the contactless holding part 60 and flows along the grooves 602 and supports the outer circumferential part 103 of the wafer 10 by air jetted from the second air jet ports 613 of the outer circumferential support parts 61. The robot hand 9 includes the four outer circumferential support parts 61 and supports the outer circumferential part 103 of the wafer 10 from the front, rear, left, and right sides. Thus, the robot hand 9 can hold the wafer 10 more stably without movement of the wafer 10 and can also invert in a state in which it holds the wafer 10. Therefore, the robot hand 9 may enter the lower side of the wafer 10 and hold the wafer 10, and thereafter the robot hand 9 may be inverted in the middle of conveyance to the temporary placement region 42.

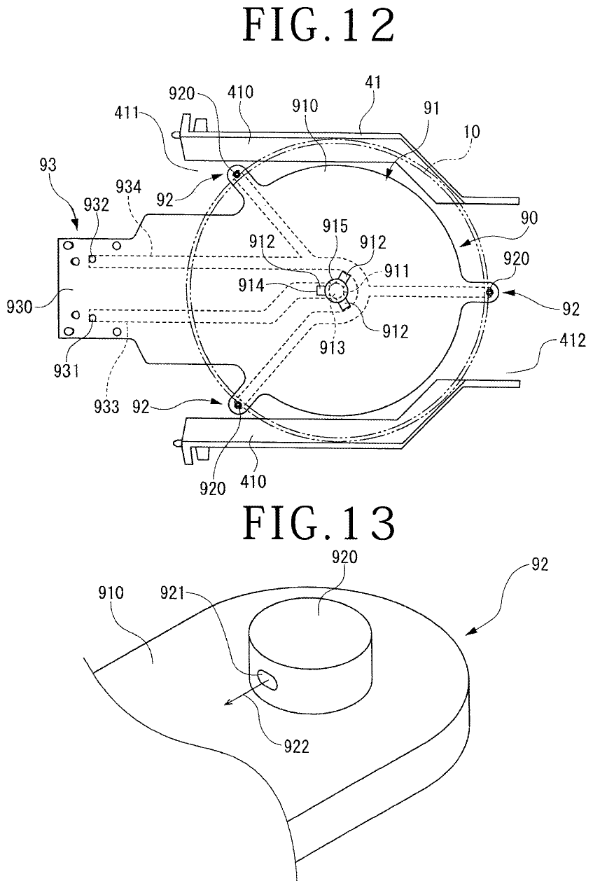

It is also possible to use a robot hand 90 illustrated in FIG. 12 instead of the robot hands 6 and 9. The robot hand 90 includes a contactless holding part 91 that contactlessly holds a surface of the wafer 10, three outer circumferential support parts 92 that contactlessly support the outer circumferential edge of the wafer 10, and an attached part 93 attached to the rotational drive part 53 illustrated in FIG. 1.

A first air inlet 931 and a second air inlet 932 are each opened and formed in an upper surface 930 of the attached part 93. The first air inlet 931 communicates with a first air flow path 933 formed inside, and the second air inlet 932 communicates with a second air flow path 934 formed inside.

At the center of an upper surface 910 of the contactless holding part 91, a first air jet port 911 that communicates with the first air flow path 933 and is opened to the side of the upper surface 910 is provided. Three grooves 912 that radially extend from the first air jet port 911 are formed on the outer circumferential side of the first air jet port 911. Similarly to the grooves 602 of the robot hands 6 and 9, the grooves 912 are formed in such a manner that the depth of the side of one end 913 that is the end on the central side of the contactless holding part 91 and at a coupling part to the first air jet port 911 is the deepest and the depth of the groove 912 becomes shallower toward the side of the other end 914 at a position that exists outside relative to the first air jet port 911 and does not reach the outer circumference of the contactless holding part 91, and the same height as the upper surface 910 is reached on the side of the other end 914. The other ends 914 are located on the inner circumferential side relative to the outer circumference of the wafer 10 to be held.

The upper side of the first air jet port 911 is covered by a circular plate 915. The circular plate 915 is bonded to a part in which the groove 912 is not formed in the upper surface 910. Air ejected from the first air jet port 911 passes through the grooves 912 and flows to the upper surface 910. The grooves 912 may be formed into a fan shape through widening of the side of the other end 914.

As illustrated in FIG. 13, each outer circumferential support part 92 includes a protruding part 920 that protrudes upward from the upper surface 910 and has a circular column shape and a second air jet port 921 that is formed in a side surface of the protruding part 920 and is opened toward the center of the contactless holding part 91. The second air jet ports 921 communicate with the second air flow path 934 illustrated in FIG. 12. The three second air jet ports 921 are disposed at equal intervals, i.e. at every 120 degrees.

When air is supplied to the first air inlet 931, the air passes through the first air flow path 933 and is ejected from the first air jet port 911 and radially flows along the upper surface 910. Thus, a suction force based on the Bernoulli effect is generated around the air. On the other hand, when air is supplied to the second air inlet 932, the air passes through the second air flow path 934 and is ejected as air 922 from the second air jet ports 921 illustrated in FIG. 13. The air 922 is ejected toward the outer circumferential part 103 of the wafer 10 and the wafer 10 is contactlessly supported without shift in the horizontal direction.

As illustrated in FIG. 12, the other ends 914 of the grooves 912 are oriented in directions in which a protruding part 920 does not exist. That is, the other ends 914 are disposed in regions that exist in directions in which the protruding part 920 does not exist as viewed from the first air jet port 911. Therefore, the air jetted from the first air jet port 911 does not go toward the protruding part 920 and does not interfere with the air 922 jetted from the second air jet ports 921. Thus, holding of the wafer 10 in the surface direction by the contactless holding part 91 and holding of the wafer 10 in the horizontal direction by the outer circumferential support parts 92 can both be achieved without imposing an adverse effect on each other. The can hold the wafer 10 completely contactlessly. In the robot hand 90 illustrated in FIG. 12, the set of the first air inlet 931 and the first air flow path 933 and the set of the second air inlet 932 and the second air flow path 934 are independent of each other. Therefore, the amount of air ejected from the first air jet port 911 and the amount of air ejected from the second air jet ports 921 can be individually controlled. In particular, by controlling the amount of air ejected from the second air jet ports 921 according to the thickness of the wafer 10, the wafer 10 can be stably supported irrespective of the thickness of the wafer 10.

Air flow paths that each communicate with a respective one of the second air jet ports 921 may be individually disposed and air inlets may be each made for a respective one of the air flow paths.

The wafer 10 conveyed to the temporary placement region 42 by the robot hand 6, the robot hand 9, or the robot hand 90 is placed on the placement table 43 in a state in which the upper surface 101 is oriented upward. Then, the jet of the air 63 and the air 65 of the robot hand 6 is stopped by stopping the supply of the air to the air inlets 621 illustrated in FIG. 2 and so forth and the robot hand 6 is separated from the wafer 10. Thereafter, the multiple pins 44 move toward the center of the placement table 43 and thereby the position of the wafer 10 is adjusted to a predetermined position.

Next, suction adhesion of the upper surface 101 of the wafer 10 is executed by the suction adhesion part 83 of the first conveying unit 81 and the wafer 10 is conveyed to the chuck table 2 by a pivot of the arm part 82. In the chuck table 2, a lower surface 102 of the wafer 10 is suction-held by the holding surface 200.

Subsequently, the chuck table 2 moves in the +Y direction and is positioned below the grinding unit 3. Then, the chuck table 2 rotates. In addition, the motor 32 rotates the grinding wheel 34 and the motor 72 of the grinding feed unit 7 lowers the grinding unit 3 by rotating the ball screw 70 to bring the grinding abrasive stones 341 that rotate into contact with the upper surface 101 of the wafer 10 and execute grinding. During the grinding, the thickness of the wafer 10 is measured by the thickness measuring instrument 67. When the wafer 10 has reached a predetermined thickness, the grinding feed unit 7 raises the grinding abrasive stones 341 to end the grinding.

After the end of the grinding, the chuck table 2 moves in the −Y direction and is positioned near the second conveying unit 84. Next, the suction adhesion part 86 of the second conveying unit 84 causes suction adhesion of the ground upper surface 101, the wafer 10 is placed on the spinner table 46 of the spinner cleaning unit 45 by a pivot of the arm part 85, and the side of the lower surface 102 is suction-held. Then, the spinner table 46 rotates and a cleaning liquid is ejected from the nozzle that is not illustrated in the diagram toward the upper surface 101 of the wafer 10, so that the upper surface 101 is cleaned.

When the cleaning of the upper surface 101 has ended, the robot 5 moves the robot hand 6 to the upper side of the wafer 10 and causes the robot hand 6 to face the upper surface 101 of the wafer 10 in a state in which the contactless holding part 60 of the robot hand 6 is oriented downward. Then, air is supplied to the air inlets 621 illustrated in FIG. 2 and so forth, and the air 63 is jetted from the first air jet port 601. In addition, the air 65 is jetted from the second air jet ports 613 illustrated in FIG. 10. Thereby, the side of the upper surface 101 of the wafer 10 is held, and the wafer 10 is supported without moving in the horizontal direction.

It is preferable for the second air jet ports 613 to jet the air toward a position at the center in the thickness direction on the side surface 103 of the wafer 10. However, when the wafer 10 is thinly ground, the second air jet ports 613 may be formed in such a manner that the air 65 jetted from the second air jet ports 613 flows to the lower surface 102 of the wafer 10. Furthermore, when a protective tape is stuck to the lower surface 102 of the wafer 10, the air 65 may be caused to flow to the surface (lower surface) of the protective tape.

That is, the wafer 10 may be supported without moving in the horizontal direction by friction between the air 65 and the lower surface 102 of the wafer 10.

The second air jet ports may be formed in such a manner that the air 65 is jetted in a spiral manner.

In this state, the raising-lowering drive part 52 raises the robot hand 6 and causes the arm 51 to pivot to cause the robot hand 6 to enter the inside of the cassette 41. Then, the state in which end parts of the wafer 10 are located over the shelf plates 410 as illustrated in FIG. 7 is made, and the robot hand 6 is lowered to place the wafer 10 on the shelf plates 410. Then, the holding of the wafer 10 is released by stopping the supply of the air to the air inlets 621. The wafer 10 is housed in the cassette 41 in this manner. Thereafter, the robot hand 6 is evacuated from the cassette 41.

In a case of conveying the wafer 10 from the spinner table 46 to the cassette 47 by using the robot hand 9 illustrated in FIG. 11, the front and back sides of the robot hand 9 can be inverted in the middle of the conveyance. In this case, the robot hand 9 is caused to enter the inside of the cassette 47 in a state in which the wafer 10 is held from the lower side. When the wafer 10 is placed on the shelf plates 470, by the robot 5, the robot hand 9 that holds the wafer 10 by the upper surface is caused to enter to a height position between the shelf plates 470 and the shelf plates 470 and a position at which the shelf plates 470, the contactless holding part 60, and the outer circumferential support parts 61 do not interfere with each other as viewed from the upper side, and thereafter the robot hand 9 is lowered. When the robot hand 9 passes through the shelf plates 470, the flow of the air 63 is inhibited by the parts that support the wafer 10 from the lower side in the shelf plates 470, and the suction force is weakened. Then, due to placement of the wafer 10 on the shelf plates 470, the wafer 10 is separated from the robot hand 9.

When the robot hand 9 passes through the shelf plates 470 downward, the supply of the air may be stopped.

Also when the wafer 10 is housed in the cassette 41, the wafer 10 can be contactlessly held, and positional shift in the horizontal direction can be prevented similarly to when the wafer 10 is carried out from the cassette 41. In particular, after the grinding, grinding dust adheres to the upper surface 101, even after the cleaning in the spinner cleaning unit 45, in some cases. However, the grinding dust does not adhere to the robot hand 6 due to the contactless holding of the wafer 10. Therefore, adhesion of the grinding dust to the wafer 10 to be ground later and be housed in the cassette 41 can be prevented. Furthermore, scratching of the wafer 10 due to contact can be prevented, and the occurrence of dust due to contact and contamination of the wafer 10 after cleaning can be prevented.

Moreover, also in a case of conveying, after spinner cleaning, to the cassette 41, a wafer in which a recessed part is formed at a central part through grinding of only the central part of the wafer and avoidance of grinding of an outer circumferential part in order to make subsequent handling such as conveyance easy, the wafer can be contactlessly held.

When the wafer 10 before grinding is conveyed from the cassette 41 to the temporary placement region 42, a robot hand of a contact type may be used. In this case, as in Japanese Patent No. 6853646, a contact-type surface may be employed as one surface, a contactless-type surface may be employed as the other surface, and the contactless-type surface may be configured as in the present invention.

Furthermore, although the configuration including the grooves 602 that radially extend in the contactless holding part 60 is employed in the present embodiment, a mortar-shaped air flow path may be employed instead of the grooves 602.

Moreover, in the present embodiment, the air 63 is radially jetted by covering the upper side of the first air jet port 601 by the circular plate 605. However, multiple first air jet ports may be formed, and each of them may be formed to jet air toward the outer circumferential side. In this case, the circular plate becomes unnecessary.

Although explanation has been made about a grinding apparatus in the present embodiment, the present invention can be applied also to a polishing apparatus.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A robot hand that is attached to a robot and contactlessly holds a wafer, the robot hand comprising:
a contactless holding part that has a first air jet port that radially jets air from a center toward an outer circumference and contactlessly holds the wafer through radial flowing of the air jetted from the first air jet port and generation of a negative pressure due to the air; and
an outer circumferential support part that has a second air jet port that is disposed to be oriented toward a center of the wafer held by the contactless holding part and jets air toward an outer circumferential edge of the wafer, the outer circumferential support part supporting the wafer without movement of the wafer by the air jetted from the second air jet port.

2. The robot hand according to claim 1, wherein
the contactless holding part includes multiple grooves that extend in a radial direction in such a manner that one ends are located on a central side and other ends do not reach the outer circumference, the multiple grooves being radially disposed around a center of a holding surface that contactlessly holds the wafer,
the grooves become shallower toward the other ends,
the first air jet port is disposed at the one ends of the grooves and jets the air to the grooves, and
the outer circumferential support part has at least a first outer circumferential support part and a second outer circumferential support part disposed to be opposed to each other, and the first outer circumferential support part and the second outer circumferential support part each have at least two of the second air jet ports.
